(19) United States
(12) Patent Application Publication
(10) Pub. No.: US 2013/0223139 A1
(43) Pub. Date: Aug. 29, 2013

(54) SEMICONDUCTOR DEVICE

(71) Applicant: Kimitoshi OKANO, Tokyo (JP)

(72) Inventor: Kimitoshi OKANO, Tokyo (JP)

(21) Appl. No.: 13/621,487

(22) Filed: Sep. 17, 2012

(30) Foreign Application Priority Data
Feb. 29, 2012 (JP) 2012-043254

(51) Int. Cl. H01L 29/78; G11C 11/34

(52) U.S. Cl. 365/157; 257/288; 257/E29.255

(57) ABSTRACT

According to one embodiment, a semiconductor device includes: a fin formed on a semiconductor substrate; a piezoelectric element that applies stress to the fin; a gate electrode that applies voltage to the fin and the piezoelectric element; and source/drain regions formed on the fin so as to sandwich a channel region formed on the fin.

### CROSS-REFERENCE TO RELATED APPLICATIONS

This application is based upon and claims the benefit of priority from Japanese Patent Application No. 2012-043254, filed on Feb. 29, 2012; the entire contents of which are incorporated herein by reference.

### FIELD

Embodiments described herein relate generally to a semiconductor device.

### BACKGROUND

There have been proposed 1T (Transistor) memories that constitute a memory device with a single transistor, such as FBC (Floating Body Cell), or TRAM (Thyristor RAM). Most of these memories are volatile memories that aim to replace 1T/1C DRAM into 1T DRAM. There have also been proposed SONOS non-volatile 1T memories utilizing an ONO membrane as a charge trap film. However, they need voltage of 10 V or more for writing data or erasing data, which is a problem from the viewpoint of power consumption and reliability of a device. Accordingly, a non-volatile 1T memory that can operate at low voltage has been demanded.

### BRIEF DESCRIPTION OF THE DRAWINGS

FIG. 1A is a perspective view illustrating a schematic configuration of a semiconductor device according to a first embodiment;

FIG. 1B is a sectional view taken along a line A-A in FIG. 1A;

FIG. 1C is a sectional view illustrating a stress generating process in a fin in the structure illustrated in FIG. 1B;

FIG. 2 is a view illustrating a relationship between a stress on a side face of the fin illustrated in FIG. 1A and a rate of change of mobility;

FIG. 3 is a view illustrating a relationship between a gate voltage and a polarization state of a piezoelectric element, before an imprint process (described later) is executed to the piezoelectric element;

FIG. 4 is a view illustrating a relationship between a gate voltage and a polarization state of the piezoelectric element, after the imprint process (described later) is executed to the piezoelectric element;

FIG. 5A is a timing chart illustrating a waveform of the gate voltage and a drain voltage in a write, a hold, and a read of data ‘1’;

FIG. 5B is a timing chart illustrating a waveform of the gate voltage and the drain voltage in a write, a hold, and a read of data ‘0’, wherein a source is grounded (0 V is applied) during the operation of the semiconductor device, although FIG. 5 does not illustrate a waveform of the source voltage, and the source voltage will not be described below;

FIG. 6A is a perspective view illustrating a schematic configuration of a semiconductor device according to a second embodiment;

FIG. 6B is a sectional view taken along a line A-A in FIG. 6A;

FIG. 7A is a sectional view illustrating a schematic configuration of a semiconductor device according to a third embodiment;

FIG. 7B is a sectional view illustrating a polarization state of a piezoelectric element when the gate voltage is applied; and

FIG. 7C is a sectional view illustrating a stress generating state of a semiconductor layer when the gate voltage is applied.

### DETAILED DESCRIPTION

In general, according to one embodiment, a semiconductor device includes a fin, a gate electrode, a gate insulating film, source/drain regions, and a piezoelectric element. The fin is formed on a semiconductor substrate. The piezoelectric element is formed on the fin. The gate electrode is formed to cover the fin through the gate insulating film and the piezoelectric element, which are formed on the surface of the fin. The gate electrode applies voltage to the piezoelectric element, thereby applying stress to the fin, and can adjust a drain current by changing a channel potential of a fin field-effect transistor. The semiconductor device according to the embodiments will be described with reference to the drawings. The present invention is not limited to the embodiments described below.

### First Embodiment

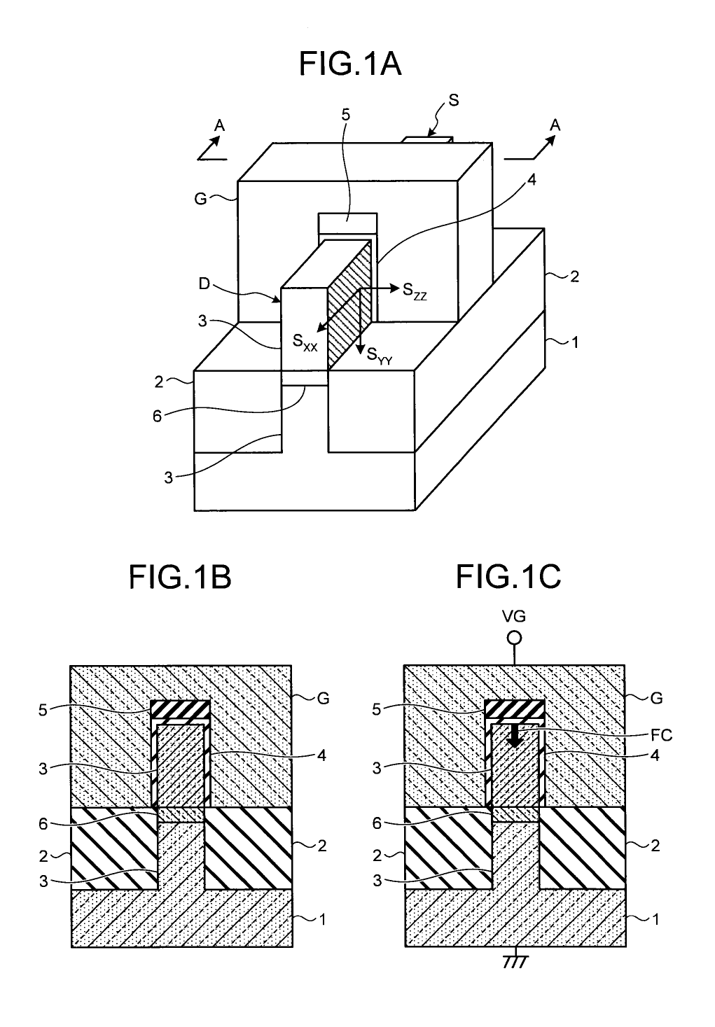

FIG. 1A is a perspective view illustrating a schematic configuration of the semiconductor device according to a first embodiment, FIG. 1B is a sectional view taken along a line A-A in FIG. 1A, and FIG. 1C is a sectional view illustrating a stress generating process in the fin in the structure illustrated in FIG. 1B.

In FIGS. 1A and 1B, a fin 3 is formed on a semiconductor substrate 1. The material of the semiconductor substrate 1 can be selected from Si, Ge, SiGe, GaAs, InP, GaP, InGaAs, GaN, and SiC. The conductive type of the semiconductor substrate 1 and the fin 3 can be set to P-type. Boron can be used as a P-type impurity, for example.

A buried insulating layer 2 is formed on the semiconductor substrate 1 in such a manner that the fin 3 is buried therein. The buried insulating layer 2 has a function of an isolation layer (STI: Shallow Trench Isolation). The height of the buried insulating layer 2 can be set such that the top of the fin 3 projects from the buried insulating layer 2. A silicon oxide film can be used as the material of the buried insulating layer 2, for example. A piezoelectric element 5 that applies stress to the fin 3 is formed on the fin 3. A piezoelectric ceramic such as barium titanate can be used as the material of the piezoelectric element 5.

A gate electrode G that applies voltage to the side face of the fin 3 and the piezoelectric element 5 is formed on the buried insulating layer 2. The gate electrode G is formed to cover the fin 3 through a gate insulating film 4 and the piezoelectric element 5. For example, the gate electrode G can be arranged to cross the piezoelectric element 5 on both side faces of the fin 3. A silicon oxide film can be used as the material of the gate insulating film 4, for example. A polycrystalline silicon film can be used as the material of the gate electrode G, for example. Alternatively, the material of the gate electrode G may be a single metal compound such as titanium nitride, tantalum carbide, lanthanum materials, aluminum materials, or magnesium materials, or a combination of these metal compounds.

An impurity diffusion layer 6 is formed between the vicinity of the top end of the STI of the fin 3 and a root. The conductive type of the impurity diffusion layer 6 can be set to P-type. Boron or Indium can be used, for example, as the impurity of the impurity diffusion layer 6. The impurity concentration of the impurity diffusion layer 6 is set to be larger than the impurity concentration of the fin channel region. The impurity diffusion layer 6 can suppress a leakage current between the source and drain, flowing through the bottom region of the fin 3 below the gate electrode G. It is preferable that the impurity diffusion layer 6 does not spread over the top end of the STI of the fin 3 in order to prevent the impurity concentration of a fin channel from being increased.

A drain region D and a source region S are formed on both sides of a channel that is formed on a region where the gate electrode G and the fin 3 are overlapped. The conductive type of the drain region D and the source region S can be set to N-type. Phosphorus or Arsenic can be used, for example, as the N-type impurity.

In order to control the body potential of the fin, the impurity concentration of the channel may be slightly increased to form a partially-depleted fin field effect transistor. The piezoelectric element 5 is preferably formed to be self-aligned with the fin 3. The piezoelectric element 5 formed on the fin 3 may protrude from the region where the gate electrode G and the fin 3 are overlapped, and extend toward the source region and the drain region D. The surface orientation of the side face of the fin on which the channel is formed is preferably (110).

In FIG. 10, when a gate voltage VG is applied to the gate electrode G with the semiconductor substrate 1 being grounded, voltage is applied to the piezoelectric element 5 in the vertical direction. Thus, the piezoelectric element 5 expands to be deformed in the height direction of the fin 3, whereby compressive stress FC is applied to the fin 3 in the height direction. As a result, the electron mobility in the channel on the side face of the fin 3 is increased, whereby the on-current of the fin field effect transistor is increased. Accordingly, the semiconductor device can be used as a resistive random access memory by utilizing the change in the on-current or the resistance change.

When the fin 3 and the piezoelectric element 5 are integrally processed, and the piezoelectric element 5 is formed in a self-aligned manner on the fin 3, the increase in the number of the process steps required to form the piezoelectric element 5 can be minimized, and the increase in a footprint of the fin field effect transistor, which is caused by the formation of the piezoelectric element 5, can be suppressed.

Since the gate electrode G is arranged on both side faces of the fin 3 as crossing the piezoelectric element 5, data can be written, erased, and read through the application of voltage to the gate electrode G. Therefore, the semiconductor device does not need a circuit dedicated to drive the piezoelectric element 5.

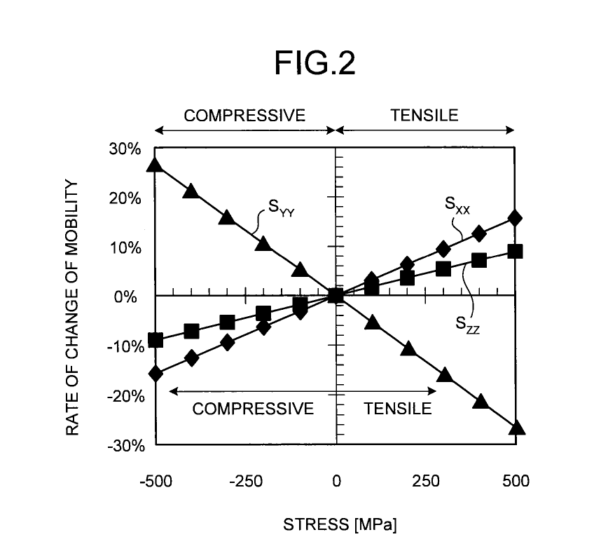

FIG. 2 is a view illustrating a relationship between stress on the side face of the fin in FIG. 1A and a rate of change of mobility in the fin side channel. In this example, stresses S_{XX}, S_{YY}, and S_{ZZ} (minus sign denotes compressive stress and plus sign denotes tensile stress) are separately applied to the N-channel fin field effect transistor whose surface orientation of the side face is (110) and the rate of change of the electron mobility in the fin side channel in three directions (X, Y, Z) is illustrated.

It is found from FIG. 2 that the sensitivity to the change in the electron mobility by the stress S_{YY} in the height direction (Y direction) of the fin is the largest. Therefore, the semiconductor device can be employed as a resistive random access memory having larger resistance change by utilizing the change in the electron mobility caused by the stress S_{YY} in the Y direction of the N-channel fin field effect transistor whose (110) surface is the channel surface. Here, a memory in which the low-resistance state corresponds to data “1”, and a high-resistance state corresponds to data “0” can be configured. The N-channel fin field effect transistor is operated in a triode mode, and the magnitude of the drain current in this case is detected, whereby it can be determined whether the data “1” is stored or the data “0” is stored.

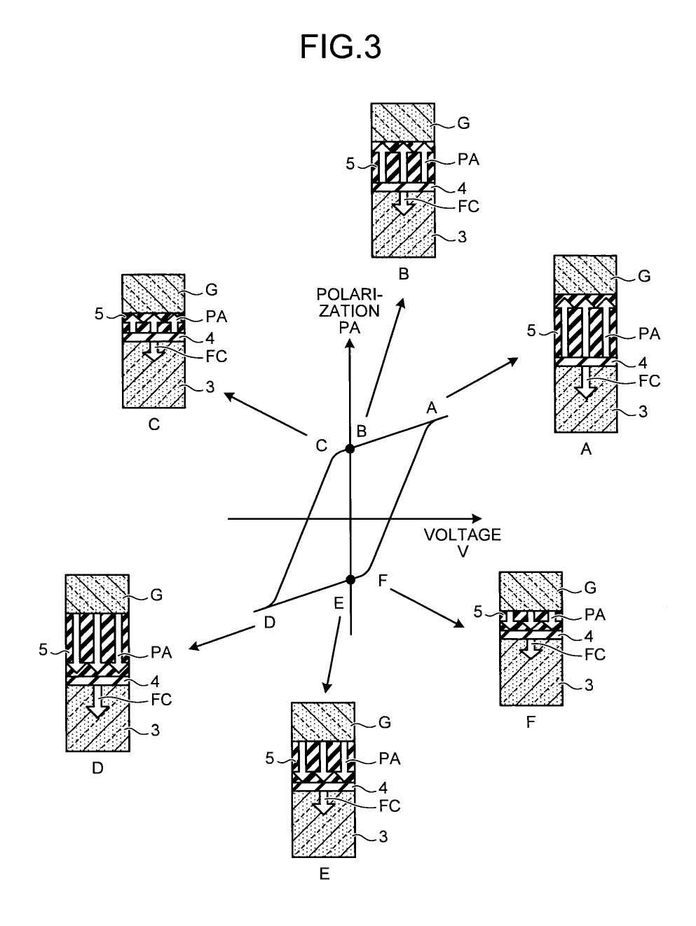

FIG. 3 is a view illustrating a relationship between the gate voltage and a polarization state of the piezoelectric element, before an imprint process is performed to the piezoelectric element. In the description below, the polarization in the direction from the fin 3 to the gate electrode G is referred to as a positive polarization, while the polarization in the direction from the gate electrode G to the fin 3 is referred to as a negative polarization.

In FIG. 3, the piezoelectric element 5 is a ferromagnetic body. Therefore, the relationship between the voltage V applied to the piezoelectric element 5 and the polarization PA shows a hysteresis curve. The hysteresis curve is symmetric with respect to a point where the voltage V and the polarization PA are both zero. The representative six points are defined as A to F. The points B and E show polarizations PA when the voltage V is zero, and they are called residual polarizations. As for sets of A and D points, B and E points, and C and F points, the signs of the voltage V are reverse to each other, the absolute values of the voltage V are equal to each other, the directions of the polarization PA are reverse to each other, and the magnitudes of the polarization PA are equal to each other. When the polarization PA is positive, the magnitude of the polarization PA increases with the change of C→B→A, so that the expansion of the piezoelectric element 5 increases. Accordingly, the compressive stress FC applied to the fin 3 increases, resulting in that the electron mobility in the fin side channel with (110) surface orientation increases. When the polarization PA is negative, the magnitude of the polarization PA increases with the change of F→E→D, so that the expansion of the piezoelectric element 5 increases. Accordingly, the compressive stress FC applied to the fin 3 increases, resulting in that the electron mobility in the fin side channel with (110) surface orientation increases.

When the residual polarizations of B and E points upon the voltage of zero are utilized, the semiconductor device is expected to be used as a non-volatile memory that can retain data even if the voltage is zero. However, in the case of the hysteresis curve that is symmetric with respect to the points where the voltage V and the polarization PA are both zero as illustrated in FIG. 3, it cannot be used as the non-volatile memory, since the magnitudes of the residual polarization upon the voltage of zero (on the B and E points) are equal to each other.

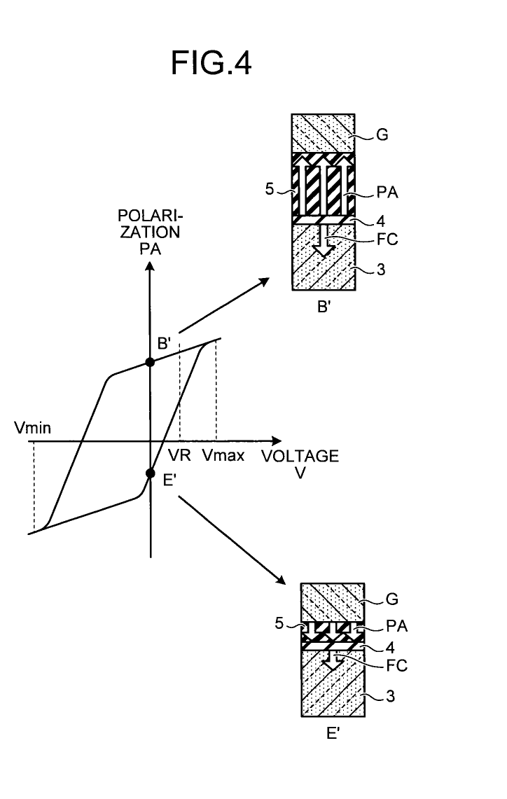

FIG. 4 is a view illustrating a relationship between the gate voltage and the polarization state of the piezoelectric element, after the imprint process is performed to the piezoelectric element.

When the hysteresis curve is asymmetric with respect to the points where the voltage V and the polarization PA are both zero as illustrated in FIG. 4, the magnitudes of the polarization PA upon the voltage V of zero (on points B′ and E′) are different from each other. Therefore, the compressive stress FC applied to the fin 3 is different between the point B′ and the point E′, so that the mobility is also different. When the polarization PA on the point B′ is associated with the data “1”, and the polarization PA on the point E′ is associated with the data “0”, for example, drain current of the fin field effect transistor differ between the case where the data “1” is stored and the case where the data “0” is stored. It can be determined whether the data “1” is stored or the data “0” is stored by detecting which drain current is larger.

There has been known a phenomenon called imprint in the ferromagnetic body in which the hysteresis curve becomes asymmetric because the ferromagnetic body is retained to be in the same polarization state for a long period. By utilizing this phenomenon, the ferromagnetic body showing the symmetric hysteresis curve illustrated in FIG. 3 can be changed to the ferromagnetic body showing the asymmetric hysteresis curve illustrated in FIG. 4.

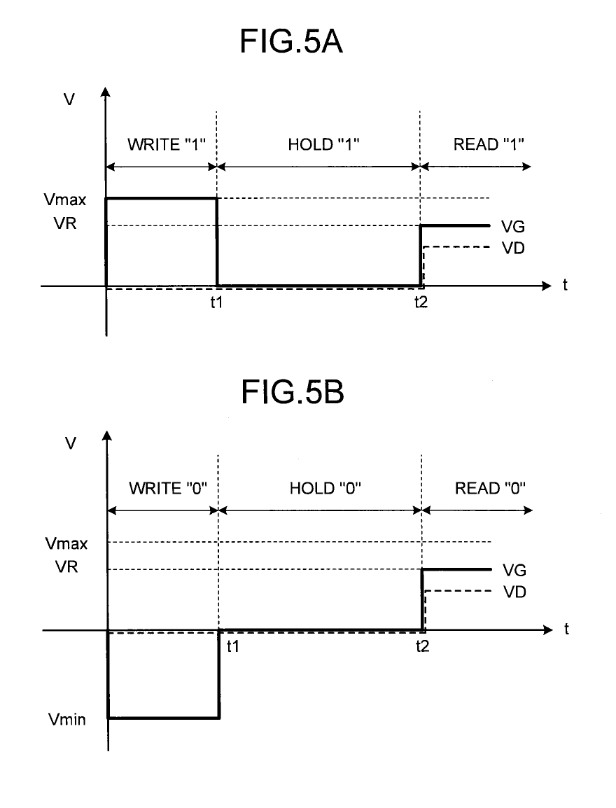

FIG. 5A is a timing chart illustrating a waveform of the gate voltage and the drain voltage during write, hold, and read of the data “1”, and FIG. 5B is a timing chart illustrating a waveform of the gate voltage and the drain voltage during write, hold, and read of the data “0”. In FIG. 4, the voltage on the turn-around at the positive-voltage side of the hysteresis curve is defined as Vmax, while the voltage on the turn-around at the negative-voltage side is defined as Vmin.

In FIG. 5A, the drain voltage VD is set to 0 V, and the gate voltage VG is swept till the voltage Vmax, during the write of the data “1”. In this case, the positive polarization is generated on the piezoelectric element 5.

The drain voltage VD and the gate voltage VG are set to 0 V, during the hold of the data “1”. In this case, the polarization PA of the piezoelectric element 5 is fixed on the B′ point in FIG. 4, so that the data “1” is retained.

During the read of the data “1”, the drain voltage VD is biased to be positive, and the gate voltage VG is set so as to satisfy 0<VD<VG<Vmax. It is desirable that the drain voltage VD and the gate voltage VG are set such that the fin field effect transistor is operated in the triode mode. In this case, the drain current corresponding to the polarization state of the piezoelectric element 5 on the B′ point flows through the fin field effect transistor. By detecting this drain current, the memory state of the data “1” can be determined.

On the other hand, in FIG. 5B, the drain voltage VD is set to 0 V, and the gate voltage VG are swept till the voltage Vmin, during the write of the data “0”. In this case, the negative polarization is generated on the piezoelectric element 5.

During the hold of the data “0”, the drain voltage VD and the gate voltage VG are both set to 0 V. In this case, the polarization PA of the piezoelectric element 5 is fixed to the E′ point in FIG. 4, so that the data “0” is retained.

During the read of the data “0”, the drain voltage VD is biased to be positive, and the gate voltage VG is set so as to satisfy 0<VD<VG<Vmax. It is desirable that the drain voltage VD and the gate voltage VG are set such that the fin field effect transistor is operated in the triode mode. In this case, the drain current corresponding to the polarization state of the piezoelectric element 5 on the E′ point flows through the fin field effect transistor. By detecting this drain current, the memory state of the data “0” can be determined.

When the gate voltage VG (=VR) during the read is set to satisfy 0<VR<Vmax, the occurrence of the data inversion (“1”→“0”) during the read can be prevented.

The method of operating the semiconductor device provided with the piezoelectric element 5 on the fin 3 illustrated in FIG. 1A as a non-volatile 1T memory has been described above. The semiconductor device provided with the piezoelectric element 5 on the fin 3 as illustrated in FIG. 1A may be operated as a field effect transistor. When the piezoelectric element 5 is formed on the fin 3 of the field effect transistor, the transistor characteristic can be tuned by modulating the fin side channel mobility after the LSI manufacturing is completed. As a result, variation in the electrical characteristics between different chips can be reduced, for example.

### Second Embodiment

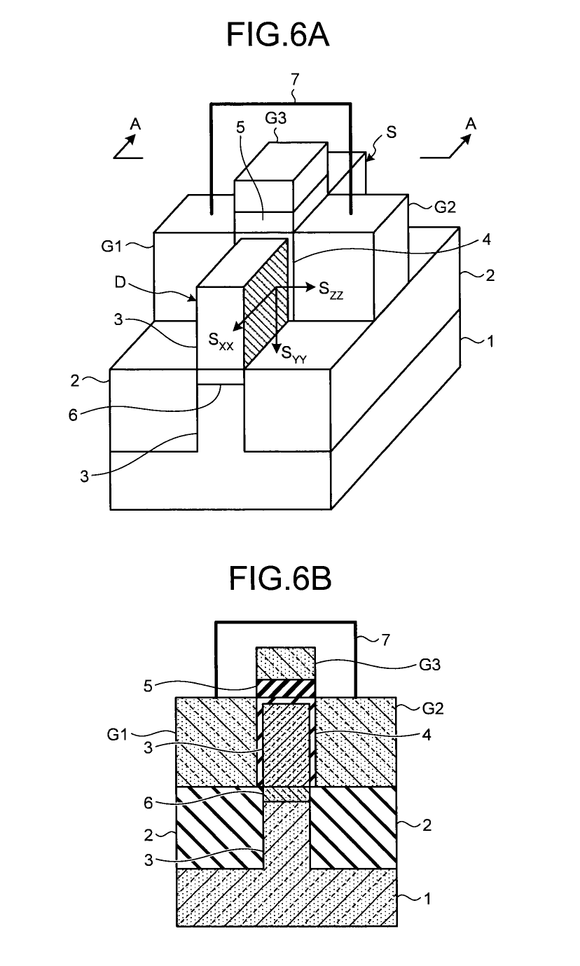

FIG. 6A is a perspective view illustrating a schematic configuration of a semiconductor device according to a second embodiment, and FIG. 6B is a sectional view taken along a line A-A in FIG. 6A.

In FIGS. 6A and 6B, the semiconductor device includes gate electrodes G1 to G3, which are electrically isolated, wherein the gate electrodes G1 and G2 are electrically connected via a wiring 7.

The gate electrodes G1 and G2 are arranged on a buried insulating layer 2 so as to be opposite to each other across the fin 3. The gate electrode G3 is arranged on the piezoelectric element 5 so as to be aligned with the gate electrodes G1 and G2 in the longitudinal direction. The lengths of the gate electrodes G1 to G3 can be set to be equal to one another. The heights of the gate electrodes G1 and G2 can be set to be equal to the height of the fin 3 that protrudes from the buried insulating layer 2. The width of the gate electrode G3 can be set to be equal to the width of the fin 3.

In FIG. 5A, the drain voltage VD is set to 0 V during the write of the data “1”. A gate voltage VG2 is applied to the gate electrode G3, and swept till the voltage Vmax.

During the hold of the data “1”, the drain voltage VD and the gate voltage VG2 applied to the gate electrode G3 are both set to 0 V.

During the read of the data “1”, the drain voltage is biased to be positive, and a gate voltage VG1 is applied to the gate electrodes G1 and G2 with 0 V being applied to the gate electrode G3. In this case, the VG1 is set to satisfy 0<VD<VG1<Vmax.

On the other hand, in FIG. 5B, the drain voltage VD is set to 0 V during the write of the data “0”. The gate voltage VG2 is applied to the gate electrode G3, and swept till the voltage Vmin.

During the hold of the data “0”, the drain voltage VD and the gate voltage VG2 applied to the gate electrode G3 are set to 0 V.

During the read of the data “0”, the drain voltage VD is biased to be positive, and the gate voltage VG1 is applied to the gate electrodes G1 and G2 with 0 V being applied to the gate electrode G3. In this case, the VG1 is set to satisfy 0<VD<VG1<Vmax.

In the present embodiment, since the voltage is not applied to the gate electrodes G1 and G2 during the write of the data, the load of the electric field to the gate insulating film 4 can be reduced, and even if high voltage is applied to the gate electrode G3, the deterioration in the reliability of the gate insulating film 4 can be prevented.

Since the gate electrode G3 is isolated from the gate electrodes G1 and G2, the deterioration in the reliability of the gate insulating film 4 can be prevented, and the high voltage can be applied to the gate electrode G3. Therefore, a larger distortion is generated on the piezoelectric element 5, whereby the modulation of the mobility in the fin side channel can be increased. Consequently, a read margin of a memory can be increased.

### Third Embodiment

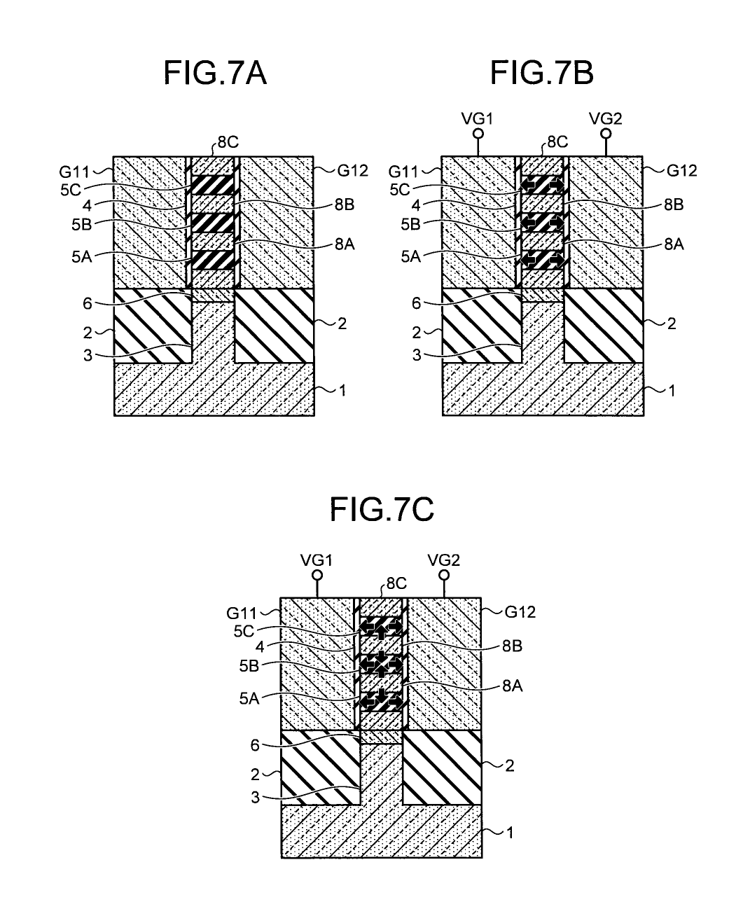

FIG. 7A is a sectional view illustrating a schematic configuration of a semiconductor device according to a third embodiment, FIG. 7B is a sectional view illustrating a polarization state of a piezoelectric element when a gate voltage is applied, and FIG. 7C is a sectional view illustrating a stress generating state of a semiconductor layer when the gate voltage is applied.

In FIG. 7A, semiconductor layers 8A to 8C and piezoelectric elements 5A to 5C are formed on a fin 3 over a buried insulating layer 2 in the semiconductor device. The semiconductor layers 8A to 8C and the piezoelectric elements 5A to 5C are alternately stacked on the fin 3. The stacked structure of the semiconductor layers 8A to 8C and the piezoelectric elements 5A to 5C can form the upper portion of the fin 3.

Gate electrodes G11 and G12 are arranged as being isolated from each other on both side faces of the stacked structure of the semiconductor layers 8A to 8C and the piezoelectric elements 5A to 5C on the fin 3 over the buried insulating layer 2. The gate electrodes G11 and G12 are arranged on the buried insulating layer 2 so as to be opposite to each other across the stacked structure of the semiconductor layers 8A to 8C and the piezoelectric elements 5A to 5C. The material of the semiconductor layers 8A to 8C can be selected from, for example, Si, Ge, SiGe, GaAs, InP, GaP, InGaAs, GaN, and SiC. The gate electrodes G11 and G12 can be set to have equal length. The heights of the gate electrodes G11 and G12 can be set such that the topmost surfaces of the gate electrodes G11 and G12 correspond with the topmost surface of the stacked structure of the semiconductor layers 8A to 8C and the piezoelectric elements 5A to 5C. The width of the stacked structure of the semiconductor layers 8A to 8C and the piezoelectric elements 5A to 5C can be set to be equal to the width of the fin 3.

In FIG. 7B, the gate voltage VG1 is applied to the gate electrode G11, and the gate voltage VG2 is applied to the gate electrode G12. If the gate voltages VG1 and VG2 are different from each other, voltage is applied to the piezoelectric elements 5A to 5C in the lateral direction. Therefore, compression is generated in the vertical direction with the extension of the piezoelectric elements 5A to 5C in the lateral direction. Accordingly, as illustrated in FIG. 7C, tensile stress is applied to the semiconductor layers 8A to 8C in the height direction. As a result, the mobility of the semiconductor layers 8A to 8C is changed depending upon the magnitude of the distortion of the piezoelectric elements 5A to 5C, whereby the semiconductor device can be used as a resistive random access memory utilizing the change in the current caused by the change in the mobility in the semiconductor layers 8A to 8C.

In the semiconductor device illustrated in FIG. 1A, the polarization is generated on the piezoelectric element 5 in the vertical direction. On the other hand, in the semiconductor device in FIG. 7A, the polarization is generated on the piezoelectric elements 5A to 5C in the lateral direction. Therefore, in order to allow the piezoelectric elements 5A to 5C to have the hysteresis curve that is asymmetric with respect to the point where the voltage and the polarization are both zero as illustrated in FIG. 4, the imprint process has to be performed to the piezoelectric elements 5A to 5C in the lateral direction.

In the description below, the polarization in the direction from the gate electrode G11 to the gate electrode G12 is referred to as positive polarization, and the polarization in the direction from the gate electrode G11 to the gate electrode G12 is referred to as negative polarization.

In the write of the data “1”, the drain voltage VD and the gate voltage VG2 are set to 0 V, and the gate voltage VG1 is swept till the voltage Vmax. In this case, the positive polarization is generated on the piezoelectric elements 5A to 5C.

In the hold of the data “1”, the drain voltage VD and the gate voltages VG1 and VG2 are set to 0 V. In this case, the polarizations of the piezoelectric elements 5A to 5C are fixed on the B′ point in FIG. 4, so that the data “1” is retained.

During the read of the data “1”, the drain voltage VD and the gate voltages VG1 and VG2 are set such that the fin field effect resistor is operated in the triode mode. In this case, the drain current corresponding to the polarization state of the piezoelectric elements 5A to 50 on the point B′ flows through the fin field effect transistor. By detecting this drain current, the memory state of the data “1” can be determined.

On the other hand, the drain voltage VD and the gate voltage VG1 are set to 0 V, and the gate voltage VG2 is swept till the voltage Vmin, during the write of the data “0”. In this case, the negative polarization is generated on the piezoelectric elements 5A to 5C.

During the hold of the data “0”, the drain voltage VD and the gate voltages VG1 and VG2 are both set to 0 V. In this case, the polarizations of the piezoelectric elements 5A to 5C are fixed to the E′ point in FIG. 4, so that the data “0” is retained.

During the read of the data “0”, the drain voltage VD and the gate voltages VG1 and VG2 are set such that the fin field effect transistor is operated in the triode mode. In this case, the drain current corresponding to the polarization state of the piezoelectric elements 5A to 5C on the E′ point flows through the fin field effect transistor. By detecting this drain current, the memory state of the data “0” can be determined.

The gate voltages VG1 and VG2 can be set to be equal to each other during the read. This can prevent the application of voltage to the piezoelectric elements 5A to 5C during the read, whereby the data inversion can be prevented from occurring.

In the present embodiment, the stacked structure in which each of the semiconductor layers 8A to 8C and each of the piezoelectric elements 5A to 5C are formed to have small thickness is used, whereby the distortion amount of the semiconductor layers 8A to 8C caused by the distortion of the piezoelectric elements 5A to 5C is increased. Accordingly, the modulation of the mobility in the channel can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a fin formed on a semiconductor substrate;
a piezoelectric element that applies stress to the fin;
a gate electrode that applies voltage to the fin and the piezoelectric element; and
source/drain regions formed on the fin so as to sandwich a channel region formed on the fin.

2. The semiconductor device according to claim 1, wherein
the piezoelectric element is arranged between the top surface of the fin and the gate electrode.

3. The semiconductor device according to claim 2, wherein
the gate electrode is arranged on both side faces of the fin as crossing the piezoelectric element.

4. The semiconductor device according to claim 2, wherein
voltage is applied to the piezoelectric element in the vertical direction, and hence, compressive stress is applied to the fin in the height direction, when voltage is applied to the gate electrode.

5. The semiconductor device according to claim 2, wherein
a surface orientation of the side face of the fin on which the fin side channel is formed is (110).

6. The semiconductor device according to claim 1, wherein
a magnitude of a residual polarization of the piezoelectric element in the direction from the fin to the gate electrode and a magnitude of a residual polarization of the piezoelectric element in the direction from the gate electrode to the fin are different from each other.

7. The semiconductor device according to claim 6, wherein,
in a hysteresis curve indicating a relationship between voltage applied to the piezoelectric element and the polarization, data “1” is written by sweeping the voltage toward the positive side till a turn-around of the hysteresis curve, data “0” is written by sweeping the voltage toward the negative side till another turn-around of the hysteresis curve, and a read operation is executed by setting the voltage to a value lower than the value when the data “1” is written.

8. The semiconductor device according to claim 7, wherein,
when the voltage at the turn-around on the positive-voltage side of the hysteresis curve is defined as Vmax, the voltage at the turn-around on the negative-voltage side is defined as Vmin, a drain voltage is defined as VD, and a gate voltage is defined as VG,
the drain voltage VD is set to 0 V, and the gate voltage VG is swept till the voltage Vmax, in a write of the data “1”, and
the drain voltage VD is set to 0 V, and the gate voltage VG is swept till the voltage Vmin, in a write of the data “0”.

9. The semiconductor device according to claim 8, wherein
the drain voltage VD is biased to be positive, and the gate voltage VG is set to satisfy 0<VD<VG<Vmax, in a read of the data.

10. The semiconductor device according to claim 9, wherein
the drain voltage VD and the gate voltage VG are set to 0 V in a hold of the data.

11. The semiconductor device according to claim 7, wherein
the gate electrode includes:
a first gate electrode that applies voltage to the fin; and
a second gate electrode that is electrically isolated from the first gate electrode, and that applies voltage to the piezoelectric element.

12. The semiconductor device according to claim 11, wherein
when the voltage at the turn-around on the positive-voltage side of the hysteresis curve is defined as Vmax, the voltage at the turn-around on the negative-voltage side is defined as Vmin, a drain voltage is defined as VD, a gate voltage of the first gate electrode is defined as VG1, and a gate voltage of the second gate electrode is defined as VG2,
the drain voltage VD is set to 0 V, and the gate voltage VG2 is swept till the voltage Vmax, in a write of the data “1”, and
the drain voltage VD is set to 0 V, and the gate voltage VG2 is swept till the voltage Vmin, in a write of the data “0”.

13. The semiconductor device according to claim 12, wherein
voltage is not applied to the first gate electrode in the write operation.

14. The semiconductor device according to claim 13, wherein
the drain voltage VD is biased to be positive, and the gate voltage VG1 is set to satisfy 0<VD<VG1<Vmax with the gate voltage VG2 being set to 0 V, in a read of the data.

15. The semiconductor device according to claim 14, wherein
the drain voltage VD and the gate voltage VG2 are set to 0 V in a hold of the data.

16. The semiconductor device according to claim 1, wherein
the upper part of the fin has a stacked structure in which a semiconductor layer and a piezoelectric element are alternately stacked.

17. The semiconductor device according to claim 16, wherein
the gate electrode includes:
a first gate electrode that applies voltage to a first side face of the stacked structure; and
a second gate electrode that is electrically isolated from the first gate electrode, and that applies voltage to a second side face of the stacked structure.

18. The semiconductor device according to claim 17, wherein
a magnitude of a residual polarization of the piezoelectric element in the direction from the first gate electrode to the second gate electrode and a magnitude of a residual polarization of the piezoelectric element in the direction from the second gate electrode to the first gate electrode are different from each other.

19. The semiconductor device according to claim 18, wherein,
in a hysteresis curve indicating a relationship between voltage applied to the piezoelectric element and the polarization, data “1” is written by sweeping the voltage toward the positive side till a turn-around of the hysteresis curve, data “0” is written by sweeping the voltage toward the negative side till another turn-around of the hysteresis curve, and a reading operation is executed by setting the voltage to a value lower than the value when the data “1” is written.

20. The semiconductor device according to claim 19, wherein
when the voltage at the turn-around on the positive-voltage side of the hysteresis curve is defined as Vmax, the voltage at the turn-around on the negative-voltage side is defined as Vmin, a drain voltage is defined as VD, a gate voltage of the first gate electrode is defined as VG1, and a gate voltage of the second gate electrode is defined as VG2,
the drain voltage VD and the gate voltage VG1 are set to 0 V, and the gate voltage VG2 is swept till the voltage Vmax, in a write of the data “1”,
the drain voltage VD and the gate voltage VG2 are set to 0 V, and the gate voltage VG1 is swept till the voltage Vmin, in a write of the data “0”,
the drain voltage VD and the gate voltages VG1 and VG2 are set in order that the fin field effect transistor is operated in a triode mode, in a read of the data, and
the drain voltage VD and the gate voltages VG1 and VG2 are set to 0 V in a hold of the data.
